(19) United States
(12) Patent Application Publication
(10) Pub. No.: US 2013/0160831 A1
(43) Pub. Date: Jun. 27, 2013

(54) Reactive Sputtering of ZnS(O,H) and InS(O,H) for Use as a Buffer Layer

(71) Applicants: Robert Zubeck, Los Altos, CA (US); Randy Dorn, Santa Clara, CA (US)

(72) Inventors: Robert Zubeck, Los Altos, CA (US); Randy Dorn, Santa Clara, CA (US)

(73) Assignee: MiaSole, Santa Clara, CA (US)

(21) Appl. No.: 13/334,296

(22) Filed: Dec. 22, 2011

(51) Int. Cl. H01L 31/032; H01L 21/66; H01L 31/0224; H01L 31/18

(52) U.S. Cl. 136/256; 438/94; 438/5; 136/264; 136/262; 257/E31.026; 257/E21.525

(57) ABSTRACT

A method of manufacturing a solar cell including providing a substrate, depositing a first electrode over the substrate and depositing at least one p-type semiconductor absorber layer over the first electrode. The p-type semiconductor absorber layer comprises a copper indium selenide (CIS) based alloy material. The method also includes depositing by reactive sputtering an n-type In-VI semiconductor layer over the at least one p-type semiconductor absorber layer and depositing a second electrode over the n-type In-VI semiconductor layer.

### FIELD OF THE INVENTION

The present invention relates generally to the field of photovoltaic devices, and more specifically to CIGS thin-film solar cells comprising alkali and zinc doping.

### BACKGROUND OF THE INVENTION

Copper indium diselenide (CuInSe₂, or CIS) and its higher band gap variants copper indium gallium diselenide (Cu(In,Ga)Se₂, or CIGS), copper indium aluminum diselenide (Cu(In,Al)Se₂), copper indium gallium aluminum diselenide (Cu(In,Ga,Al)Se₂) and any of these compounds with sulfur replacing some of the selenium represent a group of materials, referred to as copper indium selenide CIS based alloys, have desirable properties for use as the absorber layer in thin-film solar cells. To function as a solar absorber layer, these materials should be p-type semiconductors. This may be accomplished by establishing a slight deficiency in copper, while maintaining a chalcopyrite crystalline structure. In CIGS, gallium usually replaces 20% to 30% of the normal indium content to raise the band gap; however, there are significant and useful variations outside of this range. If gallium is replaced by aluminum, smaller amounts of aluminum are used to achieve the same band gap.

### SUMMARY OF THE INVENTION

One embodiment of this invention provides a method of manufacturing a solar cell including providing a substrate, depositing a first electrode over the substrate and depositing at least one p-type semiconductor absorber layer over the first electrode. The p-type semiconductor absorber layer comprises a copper indium selenide (CIS) based alloy material. The method also includes depositing by reactive sputtering an n-type In-VI semiconductor layer over the at least one p-type semiconductor absorber layer and depositing a second electrode over the n-type In-VI semiconductor layer.

Another embodiment of the invention provides a method of manufacturing a solar cell including providing a substrate, depositing a first electrode over the substrate and depositing at least one p-type semiconductor absorber layer over the first electrode. The p-type semiconductor absorber layer comprises a copper indium selenide (CIS) based alloy material. The method also includes depositing by reactive sputtering a first (II,III)-VI semiconductor layer over the at least one p-type semiconductor absorber layer and depositing by reactive sputtering a second (II,III)-VI semiconductor layer over the first (II,III)-VI semiconductor layer, wherein a ratio of Group VI element to at least one of Group II or Group III elements in the first (II,III)-VI semiconductor layer is smaller than the ratio of Group VI element to at least one of Group II or Group III elements in the second (II,III)-VI semiconductor layer.

Another embodiment of the invention provides a method of manufacturing a solar cell including providing a substrate, depositing a first electrode over the substrate and depositing at least one p-type semiconductor absorber layer over the first electrode. The p-type semiconductor absorber layer comprises a copper indium selenide (CIS) based alloy material. The method also includes depositing by reactive sputtering an n-type II-III-VI semiconductor layer over the at least one p-type semiconductor absorber layer and depositing a second electrode of the n-type semiconductor layer.

Another embodiment of the invention provides a solar cell including a substrate, a first electrode over the substrate and at least one p-type semiconductor absorber layer over the first electrode, wherein the p-type semiconductor absorber layer comprises a copper indium selenide (CIS) based alloy material. The solar cell also includes a first sodium doped n-type (II,III)-VI semiconductor layer on the at least one p-type semiconductor absorber layer, a second n-type (II,III)-VI semiconductor layer over the first n-type (II,III)-VI semiconductor layer and a second electrode over the a second n-type (II,III)-VI semiconductor layer.

### BRIEF DESCRIPTION OF THE DRAWINGS

FIG. 1 is a schematic side cross-sectional view of a CIS based solar cell according to one embodiment of the invention.

FIG. 2 shows a highly simplified schematic diagram of a top view of a sputtering apparatus that can be used to forming a first transition metal layer such as an alkali-containing transition metal layer, for example, a sodium-containing molybdenum film.

FIG. 3A shows a highly simplified schematic diagram of a top view of a modular sputtering apparatus that can be used to manufacture the solar cell depicted in FIG. 1. FIG. 3B illustrates schematically the use of three sets of dual magnetrons to increase the deposition rate and grade the composition of the CIS layer to vary its band gap.

FIGS. 4A and 4B are schematic side cross-sectional views of an in-process CIS based solar cell according to another embodiment of the invention.

FIGS. 5A and 5B are schematic side cross-sectional views of an in-process CIS based solar cell according to another embodiment of the invention.

### DESCRIPTION OF THE PREFERRED EMBODIMENTS

Conventional CIS or CIGS solar cells include a CdS buffer layer between the CIS or CIGS absorber layer and the top transparent conductive oxide electrode. However, cadmium is a highly toxic material. Long term or chronic exposure, such as in the workplace, has been linked to kidney and lung disorders. Even short term exposure may lead to flu-like symptoms, such as fever, chills, muscle aches. Thus, it would be advantageous to replace the CdS buffer layer with a layer comprising less toxic materials.

One embodiment of this invention provides a solar cell comprising a substrate, a first electrode located over the substrate, where the first electrode comprises a first transition metal layer, at least one p-type semiconductor absorber layer located over the first electrode, an n-type In-VI semiconductor layer located over the p-type semiconductor absorber layer, and a second electrode located over the n-type semiconductor layer.

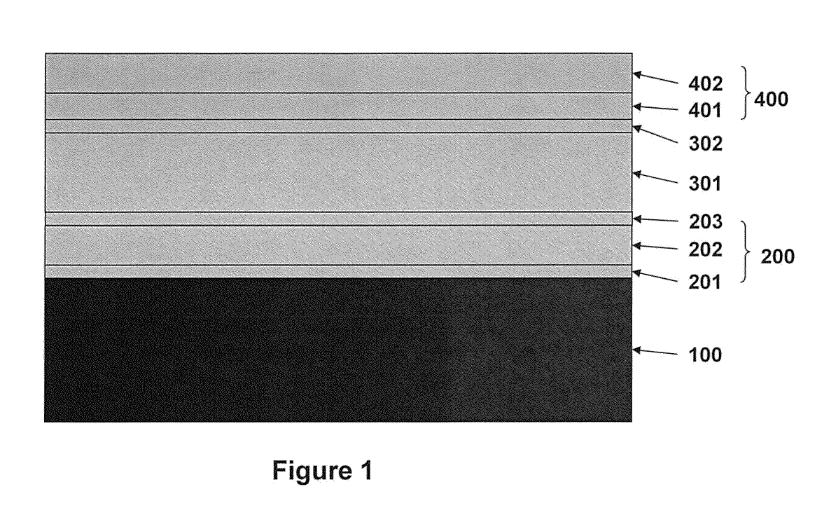

As illustrated in FIG. 1, one embodiment of the invention provides a solar cell contains a substrate 100 and a first (lower) electrode 200. The first electrode 200 comprises a first transition metal layer 202 that contains (i) an alkali element or an alkali compound and (ii) a lattice distortion element or a lattice distortion compound. Alternatively, the first transition metal layer 202 contains an alkali element or an alkali compound but substantially free of the lattice distortion element or compound.

The transition metal of the first transition metal layer 202 may be any suitable transition metal, for example but not limited to Mo, W, Ta, V, Ti, Nb, and Zr. The alkali element or alkali compound may comprise one or more of Li, Na, and K. The lattice distortion element or the lattice distortion compound may be any suitable element or compound, for example, oxygen, nitrogen, sulfur, selenium, an oxide, a nitride, a sulfide, a selenide, an organometallic compound (e.g. a metallocene, a metal carbonyl such as tungsten pentacyonyl and tungsten hexacarbonyl, and the like), or a combination thereof. For example, in a non-limiting example, the first transition metal layer 202 may comprise at least 59 atomic percent molybdenum, 5 to 40 atomic percent oxygen such as around 20 atomic percent oxygen, and 0.01 to 1.5 atomic percent sodium. In some embodiments, the first transition metal layer 202 may comprise 10²¹ to 10²³ atoms/cm³ sodium.

The first transition metal layer 202 may have a thickness of 100 to 500 nm, for example 200 to 400 nm such as around 300 nm. In some embodiments, the first transition metal layer 202 may comprise multiple sub-layers, for example 1 to 20 sub-layers such as 1 to 10 sub-layers. Each sub-layer has a different sodium concentration, resulting in a graded sodium concentration profile within the first transition metal layer 202.

In some embodiments, the lattice distortion element or the lattice distortion compound has a crystal structure different from that of the first transition metal layer to distort a polycrystalline lattice of the first transition metal layer 202. In some embodiments, when the transition metal is molybdenum, the lattice distortion element may be oxygen, forming the first transition metal layer 202 of body centered cubic Mo lattice distorted by face centered cubic oxide compositions, such as MoO₂ and MoO₃. Without wishing to be bounded to a particular theory, the density of the first transition metal layer 202 may be reduced due to a greater interplanar spacing as a result of the lattice distortion. In some other embodiments, the lattice distortion element may exist as substitutional or interstitial atoms, rather than forming a compound with other impurities or the matrix of the first transition metal layer 202.

Optionally, the first electrode 200 of the solar cell may comprise an alkali diffusion barrier layer 201 located between the substrate 100 and the first transition metal layer 202, and/or a second transition metal layer 203 located over the first transition metal layer 202. Additional adhesion layer (not shown) may be further disposed between the electrode 200 and the substrate 100, for example between the optional alkali diffusion barrier layer 201 and the substrate 100.

The optional alkali diffusion barrier layer 201 and second transition metal layer 203 may comprise any suitable materials. For example, they may be independently selected from a group consisting Mo, W, Ta, V, Ti, Nb, Zr, Cr, TiN, ZrN, TaN, VN, or combinations thereof.

In some embodiments, while the alkali diffusion barrier layer 201 is oxygen free, the first transition metal layer 202 and/or the second transition metal layer 203 may contain oxygen and/or be deposited at a higher pressure than the alkali diffusion barrier layer 201 to achieve a lower density than the alkali diffusion barrier layer 201. Of course, other impurity elements (e.g. lattice distortion elements or the lattice distortion compounds described above), instead of or in addition to oxygen, may be contained in the second transition metal layer 202 and/or the second transition metal layer 203 to reduce the density thereof.

The alkali diffusion barrier layer 201 may be in compressive stress and have a thickness greater than that of the second transition metal layer 203. For example, the alkali diffusion barrier layer 201 may have a thickness of around 100 to 400 nm such as 100 to 200 nm, while the second transition metal layer 203 has a thickness of around 50 to 200 nm such as 50 to 100 nm. While layer 201 may comprise molybdenum, in alternative embodiments it may comprise other materials, such as TiN or other barrier materials listed above.

The higher density and greater thickness of the alkali diffusion barrier layer 201 substantially reduces/prevents alkali diffusion from the first transition metal layer 202 into the substrate 100. On the other hand, the second transition metal layer 203 has a higher porosity than the alkali diffusion barrier layer 201 and permits alkali diffusion from the first transition metal layer 202 into the p-type semiconductor absorber layer 301. In these embodiments, alkali may diffuse from the first transition metal layer 202, through the lower density second transition metal layer 203, into the at least one p-type semiconductor absorber layer 301 during and/or after the step of depositing the at least one p-type semiconductor absorber layer 301.

Alternatively, the optional alkali diffusion barrier layer 201 and/or optional second transition metal layer 203 may be omitted. When the optional second transition metal layer 203 is omitted, the at least one p-type semiconductor absorber layer 301 is deposited over the first transition metal layer 202, and alkali may diffuse from the first transition metal layer 202 into the at least one p-type semiconductor absorber layer 301 during or after the deposition of the at least one p-type semiconductor absorber layer 301.

In preferred embodiments, the p-type semiconductor absorber layer 301 may comprise a CIS based alloy material selected from copper indium selenide, copper indium gallium selenide, copper indium aluminum selenide, or combinations thereof. Layer 301 may have a stoichiometric composition having a Group I to Group III to Group VI atomic ratio of about 1:1:2, or a non-stoichiometric composition having an atomic ratio of other than about 1:1:2. Preferably, layer 301 is slightly copper deficient and has a slightly less than one copper atom for each one of Group III atom and each two of Group VI atoms. The step of depositing the at least one p-type semiconductor absorber layer 301 may comprise reactively AC sputtering the semiconductor absorber layer from at least two electrically conductive targets in a sputtering atmosphere that comprises argon gas and a selenium containing gas (e.g. selenium vapor or hydrogen selenide). For example, each of the at least two electrically conductive targets comprises copper, indium and gallium; and the CIS based alloy material comprises copper indium gallium diselenide. In one embodiment, the p-type semiconductor absorber layer 301 may comprise 0.03 to 1.5 atomic percent sodium diffused from the first transition metal layer 202. As described above, sodium impurities may diffuse from the first transition metal layer 202 to the CIS based alloy layer 301. In one embodiment, the sodium impurities may concentrate at the grain boundaries of CIS based alloy, and may have a concentration as high as 10²¹ to 10²² atoms/cm³.

In an embodiment, an n-type semiconductor layer 302 may then be deposited over the p-type semiconductor absorber layer 301. In alternative embodiments discussed in more detail below, one or more layers are deposited on the absorber layer 301 and then annealed to form the n-type semiconductor layer. The n-type semiconductor layer 302 may comprise any suitable n-type semiconductor materials. Suitable materials for the n-type semiconductor layer 302 include but are not limited to In-VI semiconductors, such as In₂Se₃, In₂S₃, In₂(Se₁₋ₓSₓ)₃, (In_{2±y} Zn_{1±y})Se₄, (In_{2±y}Zn_{1±y})S₄ or (In_{2±y}Zn_{1±y})(Se₁₋ₓSₓ)₄, where 0<x<1, 0≦y≦1 and (InₓZn₁₋ₓ)_{2+z} (Se_{y}S_{1-y})_{3+z}, wherein 0<x≦1, 0≦y≦1, and 0≦z≦1. Other suitable semiconductor materials include (II,III)-VI semiconductors, such as semiconductor materials which include at least one of Zn and In, and at least one of S and Se, such as ZnSe:Na and Zn(Se_{y}S_{1-y}):Na, wherein 0≦y≦1. As used herein, the term “(II,III)-VI semiconductor” includes semiconductors which include: a) a Group VIA element (e.g., S and/or Se), and b) either a Group IIB element (e.g., Zn) or a Group IIIA element (e.g., In) or both a Group IIB and a Group IIIA element (e.g., both Zn and In). Preferably, but not necessarily, the VI semiconductor excludes cadmium other than unavoidable Cd impurity. As used herein, the term “II-III-VI semiconductor” includes semiconductors which include: a) a Group VIA element (e.g., S and/or Se), and b) a Group IIB element (e.g., Zn), and c) a Group IIIA element (e.g., In).

After the n-type semiconductor layer 302 is deposited, a second electrode 400, also referred to as a transparent top electrode, is further deposited over the n-type semiconductor layer 302. The transparent top electrode 400 may comprise multiple transparent conductive layers, for example, but not limited to, an Indium Tin Oxide (ITO) layer 402 located over an optional intrinsic Zinc Oxide or a resistive Aluminum Zinc Oxide (AZO, also referred to as RAZO) layer 401. Of course, the transparent top electrode 400 may comprise any other suitable materials, for example, doped ZnO or SnO.

Optionally, one or more antireflection (AR) films (not shown) may be deposited over the transparent top electrode 400, to optimize the light absorption in the cell, and/or current collection grid lines may be deposited over the top conducting oxide.

Alternatively, the solar cell may be formed in reverse order. In this configuration, a transparent electrode is deposited over a substrate, followed by depositing an n-type semiconductor layer over the transparent electrode, depositing at least one p-type semiconductor absorber layer over the n-type semiconductor layer, depositing a first transition metal layer over the at least one p-type semiconductor absorber layer, and optionally depositing a second transition metal layer between the first transition metal layer and the p-type semiconductor absorber layer and/or depositing a alkali diffusion barrier layer 201 over the first transition metal layer 202. The substrate may be a transparent substrate (e.g., glass) or opaque (e.g., metal). If the substrate used is opaque, then the initial substrate may be delaminated after the steps of depositing the stack of the above described layers, and then bonding a glass or other transparent substrate to the transparent electrode of the stack.

A solar cell described above may be fabricated by any suitable methods. In one embodiment, a method of manufacturing such a solar cell comprising providing a substrate 100, depositing a first electrode 200 over the substrate 100, depositing at least one p-type semiconductor absorber layer 301 over the first electrode 200, depositing an n-type semiconductor layer 302 over the p-type semiconductor absorber layer 301, and depositing a second electrode 400 over the n-type semiconductor layer 302. The step of depositing the first electrode 200 comprises depositing the first transition metal layer 202. While sputtering was described as the preferred method for depositing all layers onto the substrate, some layers may be deposited by MBE, CVD, evaporation, plating, etc. In some embodiments, one or more sputtering steps may be reactive sputtering.

In some embodiments, the lattice distortion element or compound may be contained in at least one of the sputtering target used for sputtering the first transition metal layer 202. For example, in some embodiments the step of sputtering the first transition metal layer 202 comprises sputtering from a target comprising a combination of the transition metal, the alkali element/compound, and the lattice distortion element/compound, for example, a sodium molybdate target. In general and without being limited to a specific composition, the target may comprise 5 to 40 atomic percent oxygen, such as around 20 atomic percent oxygen, 0.01 to 1.5 atomic percent sodium, and balance molybdenum. In some other embodiments, the step of sputtering the first transition metal layer 202 comprises sputtering from at least one pair of sputtering targets having different compositions from each other. The at least one pair of sputtering targets are selected from: (i) a first molybdenum target and a second sodium molybdate or sodium oxide target; (ii) a first molybdenum oxide target (e.g., a molybdenum target containing 5 to 40 atomic percent oxygen, such as around 20 atomic percent oxygen) and a second sodium selenide, sodium fluoride, sodium selenide or sodium sulfate target; or (iii) a first molybdenum target and a second sodium target in an oxygen containing reactive sputtering system. Preferably, the at least one pair of targets is located in the same vacuum chamber of a magnetron sputtering system.

Alternatively, reactive sputtering may be used to introduce the lattice distortion element or compound, such as oxygen, nitrogen, etc., from a gas phase instead of or in addition to from a sputtering target. A target comprising both transition metal and alkali element/compound, or a pair of target comprising one transition metal target (e.g. a Mo target) and one alkali element/compound target (e.g. a NaF target) may be used. In one embodiment, the transition metal target may be substantially free of alkali. As used herein, the term “substantially free of alkali” means that no alkali metal or other alkali-containing material is intentionally alloyed or doped, but unavoidable impurities of alkali may present. If desired, more than two targets may be used to sputter the first transition metal layer 202.

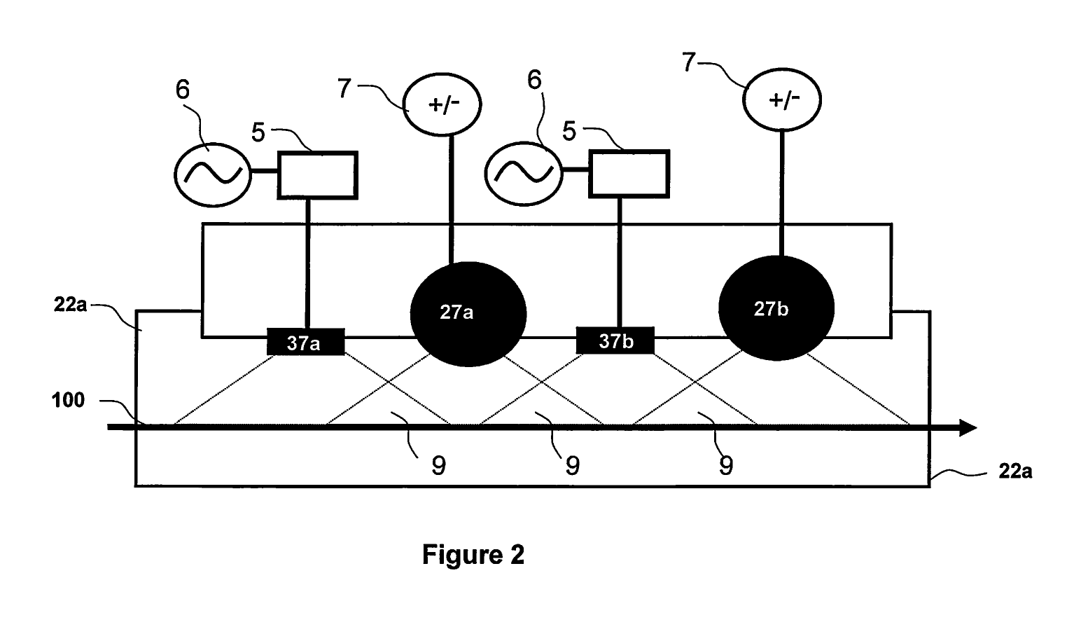

For example, by using a sputtering apparatus illustrated in FIG. 2, the first transition metal layer (not shown in FIG. 2, and referred to as layer 202 in FIGS. 1) may be deposited over a substrate 100. Targets comprising an alkali-containing material (e.g., targets 37a and 37b) and targets comprising a transition metal (e.g., 27a and 27b) are located in a sputtering process module 22a, such as a vacuum chamber. In this non-limiting example, the transition metal targets 27a and 27b are rotating Mo cylinders and are powered by DC power sources 7, and the alkali-containing targets 37a and 37b are planar NaF targets and are powered by RF generators 6 through matching networks 5. The target types alternate and end with a transition metal target, for example target 27b as shown in FIG. 2. The distance between the adjacent targets is small enough such that a sufficient overlap 9 may exist between the alternating transition and metal alkali containing fluxes and thus enhance the intermixing of the transition metal and the alkali-containing material during depositing the alkali-containing transition metal layer.

In some embodiments, the step of depositing the first transition metal layer 202 may be conducted in an oxygen and/or nitrogen rich environment, and may comprise DC sputtering the transition metal from the first target and pulsed DC sputtering, AC sputtering, or RF sputtering the alkali compound from the second target. Any suitable variations of the sputtering methods may be used. For example, for electrically insulating second target materials, AC sputtering refers to any variation of AC sputtering methods that may be used to for insulating target sputtering, such as medium frequency AC sputtering or AC pairs sputtering. In one embodiment, the step of depositing the first transition metal layer may comprise DC sputtering a first target comprising a transition metal, such as molybdenum, and pulsed DC sputtering, AC sputtering, or RF sputtering a second target comprising alkali-containing material, such as a sodium-containing material, in an oxygen rich sputtering environment.

The substrate 100 may be a foil web, for example, a metal web substrate, a polymer web substrate, or a polymer coated metal web substrate, and may be continuously passing through the sputtering module 22a during the sputtering process, following the direction of the imaginary arrow along the web 100. Any suitable materials may be used for the foil web. For example, metal (e.g., stainless steel, aluminum, or titanium) or thermally stable polymers (e.g., polyimide or the like) may be used. The foil web 100 may move at a constant or variable rate to enhance intermixing.

The sodium-containing material may comprise any material containing sodium, for example alloys or compounds of sodium with one or more of selenium, sulfur, oxygen, nitrogen or barrier metal (such as molybdenum, tungsten, tantalum, vanadium, titanium, niobium or zirconium), such as sodium fluoride, sodium molybdate, sodium fluoride, sodium selenide, sodium hydroxide, sodium oxide, sodium sulfate, sodium tungstate, sodium selenate, sodium selenite, sodium sulfide, sodium sulfite, sodium titanate, sodium metavanadate, sodium orthovanadate, or combinations thereof. Alloys or compounds of lithium and/or potassium may be also used, for example but not limited to alloys or compounds of lithium or potassium with one or more of selenium, sulfur, oxygen, nitrogen, molybdenum, tungsten, tantalum, vanadium, titanium, niobium or zirconium. The transition metal target may comprise a pure metal target, a metal alloy target, a metal oxide target (such as a molybdenum oxide target), etc.

In one embodiment, the transition metal is molybdenum, and the first transition metal layer 202 comprises molybdenum intentionally doped with oxygen and at least one alkali element, such as sodium. The oxygen can be omitted or replaced with any lattice distortion elements. Likewise, sodium may be replaced in whole or in part by lithium or potassium. The first transition layer 202 may contain elements other than molybdenum, oxygen and sodium, such as other materials that are diffused into this layer during deposition, such as indium, copper, selenium and/or barrier layer metals.

The amount of sodium diffused into the at least one p-type semiconductor absorber layer 301 may be tuned by independently controlling the thickness of deposited molybdenum sublayers and the thickness of sodium-containing sublayers in the first transition layer, by independently tuning the sputtering rate of the first target comprising molybdenum and the sputtering rate of the second target comprising sodium. A variable sodium content as a function of thickness in the sodium-containing molybdenum layer may also be generated by independently controlling the thickness of the deposited molybdenum sublayers and the thickness of the sodium-containing sublayers in the first transition metal layer 202. The molybdenum sublayers and the sodium-containing sublayers may become intermixed, forming a continuous sodium-containing molybdenum layer, during at least one of the steps of depositing the first transition metal layer 202, depositing the at least one p-type semiconductor absorber layer 301, or an optional post-deposition annealing process.

Optionally, the step of depositing the first electrode 200 further comprises depositing an alkali diffusion barrier layer 201 between the substrate 100 and the first transition metal layer 202, and depositing a second transition metal layer 203 over the first transition metal layer 202. In some embodiments, the step of sputtering the alkali diffusion barrier layer 201 occurs at a lower pressure than the step of sputtering the second transition metal layer 203.

In some embodiments, the step of sputtering the alkali diffusion barrier layer 201 occurs under a first sputtering environment in a first vacuum chamber of a magnetron sputtering system, while the step of sputtering the second transition metal layer 203 occurs under a second sputtering environment in a second vacuum chamber of the magnetron sputtering system different from the first vacuum chamber. The second sputtering environment differs from the first sputtering environment in at least one of argon pressure, oxygen pressure, or nitrogen pressure. For example, the step of sputtering the alkali diffusion barrier layer 201 may occur in an oxygen free atmosphere, while the step of sputtering the second transition metal layer 203 occurs in an oxygen containing atmosphere. For example, in some embodiments, the step of depositing the alkali diffusion barrier layer 201 may comprise sputtering from a metal target under 0.8 to 1.2 mtorr such as around 1 mtorr in an inert environment, while the step of depositing the second transition metal layer 203 comprises sputtering from an transition metal target under 2 to 8 mtorr in an oxygen and/or nitrogen rich environment. The sputtering power used for depositing the alkali diffusion barrier layer 201 and depositing the second transition metal layer 203 may also be different. For example, the sputtering power used for depositing the alkali diffusion barrier layer 201 may be higher than that used for depositing the second transition metal layer 203.

The step of sputtering the first transition metal layer 202 may occur in the first or the second vacuum chamber. For example, a first transition metal layer 202 containing lattice distortion element/compound(s) may be deposited in the second vacuum chamber in which the second transition metal layer 203 is deposited. In some other embodiments, when a first transition metal layer 202 free of lattice distortion element/compound(s) is desired, the first transition metal layer 202 may be deposited in the first vacuum chamber in which the alkali diffusion barrier layer 201 is deposited. Alternatively, the step of sputtering the first transition metal layer 202 may occur in a third vacuum chamber of the magnetron sputtering system different from the first and the second vacuum chambers.

In some embodiments, the step of depositing the first electrode 200 (comprising depositing the alkali diffusion barrier layer 201, depositing the first transition metal layer 202 and depositing the second transition metal layer 203) comprises sputtering the alkali diffusion barrier layer 201, sputtering the first transition metal layer 202, and sputtering the second transition metal layer 203 in the same sputtering apparatus.

More preferably, the steps of depositing the first electrode 200, depositing the at least one p-type semiconductor absorber layer 301, depositing the n-type semiconductor layer 302, and depositing the second electrode 400 comprise sputtering the alkali diffusion barrier layer 201, the first transition metal layer 202, the second transition metal layer 203, the p-type absorber layer 301, the n-type semiconductor layer 302 and one or more conductive films of the second electrode 400 over the substrate 100 (preferably a web substrate in this embodiment) in corresponding process modules of a plurality of independently isolated, connected process modules without breaking vacuum, while passing the web substrate 100 from an input module to an output module through the plurality of independently isolated, connected process modules such that the web substrate continuously extends from the input module to the output module while passing through the plurality of the independently isolated, connected process modules. Each of the process modules may include one or more sputtering targets for sputtering material over the web substrate 100.

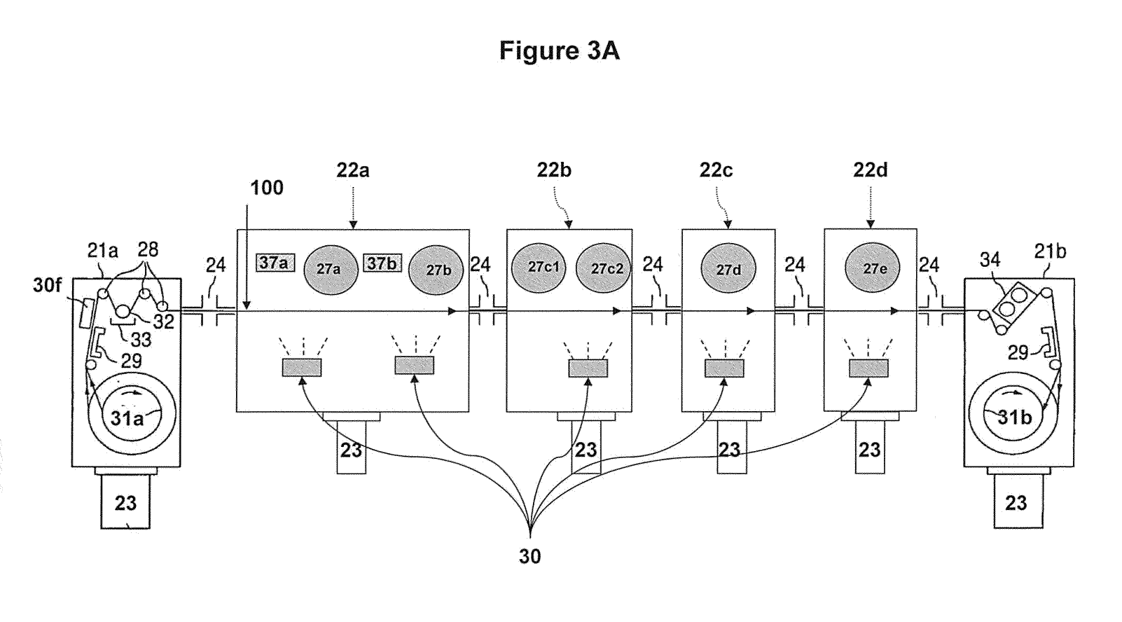

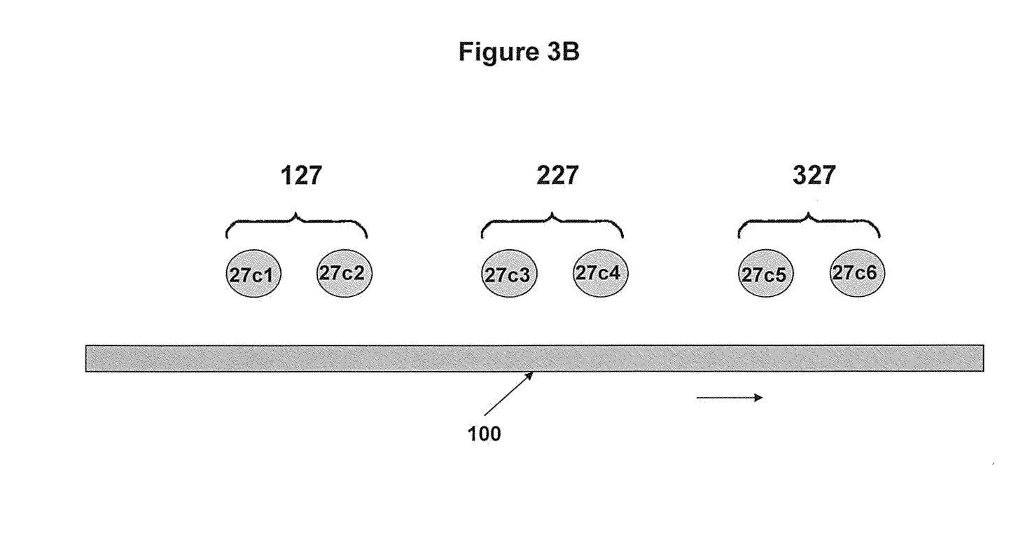

For example, a modular sputtering apparatus for making the solar cell, as illustrated in FIG. 3A (top view), may be used for depositing the layers. The apparatus is equipped with an input, or load, module 21a and a symmetrical output, or unload, module 21b. Between the input and output modules are process modules 22a, 22b, 22c and 22d. The number of process modules 22 may be varied to match the requirements of the device that is being produced. Each module has a pumping device 23, such as vacuum pump, for example a high throughput turbomolecular pump, to provide the required vacuum and to handle the flow of process gases during the sputtering operation. Each module may have a number of pumps placed at other locations selected to provide optimum pumping of process gases. The modules are connected together at slit valves 24, which contain very narrow low conductance isolation slots to prevent process gases from mixing between modules. These slots may be separately pumped if required to increase the isolation even further. Other module connectors 24 may also be used. Alternatively, a single large chamber may be internally segregated to effectively provide the module regions, if desired. U.S. Pat. No. 7,544,884 (“Hollars”) discloses a vacuum sputtering apparatus having connected modules, and is incorporated herein by reference in its entirety.

The web substrate 100 is moved throughout the machine by rollers 28, or other devices. Additional guide rollers may be used. Rollers shown in FIG. 3A are schematic and non-limiting examples. Some rollers may be bowed to spread the web, some may move to provide web steering, some may provide web tension feedback to servo controllers, and others may be mere idlers to run the web in desired positions. The input spool 31a and optional output spool 31b thus are actively driven and controlled by feedback signals to keep the web in constant tension throughout the machine. In addition, the input and output modules may each contain a web splicing region or device 29 where the web 100 can be cut and spliced to a leader or trailer section to facilitate loading and unloading of the roll. In some embodiments, the web 100, instead of being rolled up onto output spool 31b, may be sliced into solar modules by the web splicing device 29 in the output module 21b. In these embodiments, the output spool 31b may be omitted. As a non-limiting example, some of the devices/steps may be omitted or replaced by any other suitable devices/steps. For example, bowed rollers and/or steering rollers may be omitted in some embodiments.

Heater arrays 30 are placed in locations where necessary to provide web heating depending upon process requirements. These heaters 30 may be a matrix of high temperature quartz lamps laid out across the width of the web. Infrared sensors provide a feedback signal to servo the lamp power and provide uniform heating across the web. In one embodiment, as shown in FIG. 3A, the heaters are placed on one side of the web 100, and sputtering targets 27 a-e and 37 a-b are placed on the other side of the web 100. Sputtering targets 27 and 37 may be mounted on dual cylindrical rotary magnetron(s), or planar magnetron(s) sputtering sources, or RF sputtering sources.

After being pre-cleaned, the web substrate 100 may first pass by heater array 30f in module 21a, which provides at least enough heat to remove surface adsorbed water. Subsequently, the web can pass over roller 32, which can be a special roller configured as a cylindrical rotary magnetron. This allows the surface of electrically conducting (metallic) webs to be continuously cleaned by DC, AC, or RF sputtering as it passes around the roller/magnetron. The sputtered web material is caught on shield 33, which is periodically changed. Preferably, another roller/magnetron may be added (not shown) to clean the back surface of the web 100. Direct sputter cleaning of a web 100 will cause the same electrical bias to be present on the web throughout the machine, which, depending on the particular process involved, might be undesirable in other sections of the machine. The biasing can be avoided by sputter cleaning with linear ion guns instead of magnetrons, or the cleaning could be accomplished in a separate smaller machine prior to loading into this large roll coater. Also, a corona glow discharge treatment could be performed at this position without introducing an electrical bias.

Next, the web 100 passes into the process modules 22a through valve 24. Following the direction of the imaginary arrows along the web 100, the full stack of layers may be deposited in one continuous process. The first transition metal layer 202 may be sputtered in the process module 22a over the web 100, as illustrated in FIG. 3A (and previously in FIG. 1). Optionally, the process module 22a may include more than two pairs of targets, each pair of targets comprising a transition metal target 27 and an alkali-containing target 37, arranged in such a way that the types of targets alternate and the series of targets end with a transition metal target. The alkali-containing target has a composition different from that of the transition metal target.

The web 100 then passes into the next process module, 22b, for deposition of the at least one p-type semiconductor absorber layer 301. In a preferred embodiment shown in FIG. 3A, the step of depositing the at least one p-type semiconductor absorber layer 301 includes reactively alternating current (AC) magnetron sputtering the semiconductor absorber layer from at least one pair of two conductive targets 27c1 and 27c2, in a sputtering atmosphere that comprises argon gas and a selenium-containing gas. In some embodiment, the pair of two conductive targets 27c1 and 27c2 comprise the same targets. For example, each of the at least two conductive targets 27c1 and 27c2 comprises copper, indium and gallium, or comprises copper, indium and aluminum. The selenium-containing gas may be hydrogen selenide or selenium vapor. In other embodiments, targets 27c1 and 27c2 may comprise different materials from each other. The radiation heaters 30 maintain the web at the required process temperature, for example, around 400-800° C., for example around 500-600° C., which is preferable for the CIS based alloy deposition.

In some embodiments, at least one p-type semiconductor absorber layer 301 may comprise graded CIS based material. In this embodiment, the process module 22b further comprises at least two more pairs of targets (227, and 327), as illustrated in FIG. 3B. The first magnetron pair 127 (27c1 and 27c2) are used to sputter a layer of copper indium diselenide while the next two pairs 227, 327 of magnetrons targets (27c3, 27c4 and 27c5, 27c6) sputter deposit layers with increasing amounts of gallium (or aluminum), thus increasing and grading the band gap. The total number of targets pairs may be varied, for example may be 2-10 pairs, such as 3-5 pairs. This will grade the band gap from about 1 eV at the bottom to about 1.3 eV near the top of the layer. Details of depositing the graded CIS material is described in the Hollars published application, which is incorporated herein by reference in its entirety.

Optionally, the alkali diffusion barrier layers 201 may be sputtered over the substrate 100 in a process module added between the process modules 21a and 22a. The second transition metal layer 203 may be sputtered over the first transition metal layer 202 in a process module added between the process modules 22a and 22b. Further, one or more process modules (not shown) may be added to deposit additional barrier layers and/or adhesion layer to the stack, if desired.

In some embodiments, one or more process modules (not shown) may be further added between the process modules 21a and 22a to sputter a back side protective layer over the back side of the substrate 100 before the first electrode 200 is deposited on the front side of the substrate. U.S. application Ser. No. 12/379,428 (Attorney Docket No. 075122/0139) titled “Protective Layer for large-scale production of thin-film solar cells” and filed on Feb. 20, 2009, which is hereby incorporated by reference, describes such deposition process. The web 100 may then pass into the process modules 22c and 22d, for depositing the n-type semiconductor layer 302, and the transparent top electrode 400, respectively. Any suitable type of sputtering sources may be used, for example, rotating AC magnetrons, RF magnetrons, or planar magnetrons. Extra magnetron stations (not shown), or extra process modules (not shown) could be added for sputtering the optional one or more AR layers. Finally, the web 100 passes into output module 21b, where it is either wound onto the take up spool 31b, or sliced into solar cells using cutting apparatus 29.

In an embodiment, the composition of the n-type semiconductor layer 302 is controlled by providing at least one of O₂ or H₂ into a reactive sputtering atmosphere to form a (InₓZn₁₋ₓ)_{2+z} (Se_{y}S_{1-y})_{3+z} (O,H) layer, where 0≦x≦1, 0≦y≦1 and 0≦z≦1. Examples of layer 302 include InS(O, H), ZnS(O, H), (InₓZn₁₋ₓ)S(O,H) where 0<x<1. In this embodiment, the oxygen and/or hydrogen content may comprise 10 atomic percent or less of the total semiconductor material, such as 0.001 to 5 atomic percent. In the process of sputtering layer 302 in chamber 22c, the targets may comprise Zn, In or Zn-In alloy targets. The Group VI element(s) (e.g., S or Se) may be evaporated from evaporation source(s), such as evaporation pots and spargers. The oxygen and hydrogen may be supplied in a gas phase from a gas manifold or pipe which opens into the chamber 22c. Alternatively, the sulfur may be provided together with the hydrogen as a gas, such as hydrogen sulfide gas rather than being evaporated into the sputtering atmosphere.

The composition may be controlled by monitoring the reactive sputtering atmosphere and controlling the composition of the reactive sputtering atmosphere based on the results of the monitoring. The reactive sputtering atmosphere may be monitored by any suitable method, such as by plasma emission spectroscopy. The ratio of the metal (e.g., Zn and/or In) to hydrogen, oxygen, sulfur and/or selenium can be dynamically controlled based on the monitoring step by controlling the sputtering power, sputtering pressure, evaporation source temperature, hydrogen or oxygen gas flow rate, etc. to compensate for the metal loss at the absorber 301 layer interface and to improve band alignment of layers 301 and 302. For example, the reactive sputtering process may be controlled to make layer 302 slightly metal rich or Group VI deficient (e.g., more than one metal atom for each Group VI atom, including 1.01 to 1.2 metal atoms for each Group VI atom). Reactive sputtering permits different layer stoichiometries to be sputtered, which is not generally possible in RF sputtering of ceramic targets or wet plating of ZnS. It should be noted that layer 302 may be used in solar cells other than CIGS solar cells, such as solar cell having a II-VI absorber layer, such as CdTe, CdZnTeS, CdZnTeSe, etc., layers.

In another embodiment, an n-type ZnSe layer 302 may be formed by depositing a Zn or a Zn alloy layer over the absorber layer 301 and then diffusing the zinc into the top of the CIGS absorber layer 301 to form n-type Zn doped CIGS layer. In addition, if the Zn layer contains sodium, then the sodium may be diffused into the CIGS absorber layer 301 instead of or in addition to diffusing sodium from the bottom electrode 200. Thus, this embodiment may be used in combination with any one or more features of the previous embodiments described above. Alternatively, the sodium diffusion in this embodiment may take place only from the overlying zinc layer while the bottom electrode does not contain sodium. Furthermore, in this embodiment, a p-type CIGS/n-type Zn doped CIGS p-n junction (i.e., a CIGS homojunction) is formed, as described in U.S. Pat. No. 7,544,884, which is incorporated herein by reference in its entirety. Preferably, the zinc diffusion takes place at a relatively low temperature, such as less than about 200 C to form zinc doped CIGS. In contrast, at higher temperatures, such as above 200 C, interdiffusion occurs between the adjacent zinc and the CIGS layers to form a zinc selenide layer above the CIGS layer.

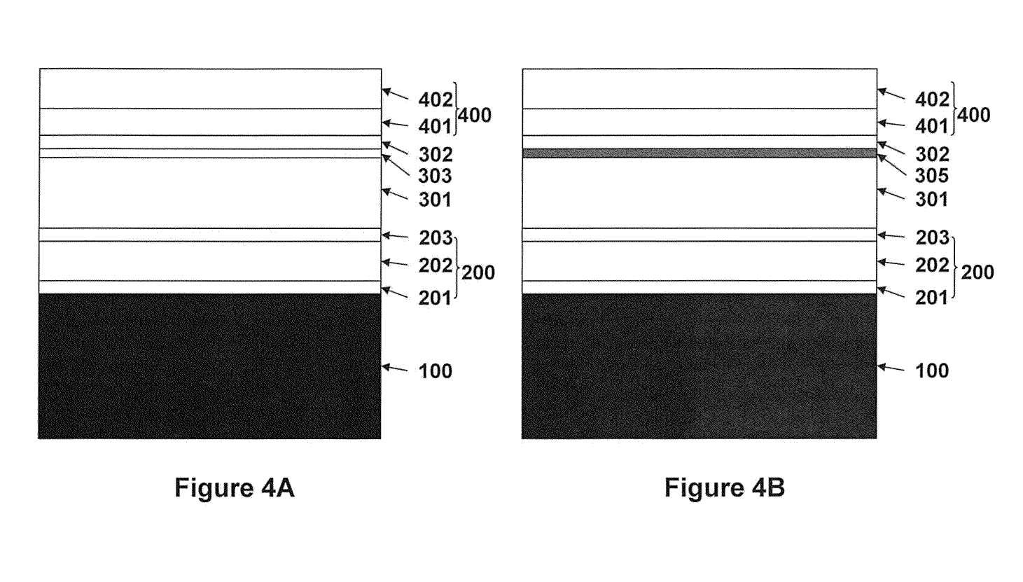

FIGS. 4A and 4B illustrate the above method of making a solar cell with a non-cadmium containing n-type semiconductor layer 302. Similar to the embodiment illustrated in FIG. 1, a first electrode 200 is deposited on a substrate 100. The first electrode 200 may comprise an optional alkali diffusion barrier layer 201, a first transition metal layer 202 and a second transition metal layer 203. At least one p-type semiconductor absorber layer 301 is then deposited on the first electrode 200.

At this point, the method diverges from the embodiment illustrated in FIG. 1. Rather than depositing the n-type semiconductor layer 302 on the absorber layer 301, a metal or metal alloy sacrificial layer 303 is deposited on the absorber layer 301. In an embodiment, the layer 303 comprises Zn metal or a Zn:Na alloy. The n-type semiconductor layer 302 is then deposited on the layer 303. The sacrificial layer may comprise a thickness of 1-5 nm, such as 1-3 nm. Layer 303 may be formed by sputtering from a zinc-based sputtering target, such DC or AC sputtering of a pure zinc target, or a Zn target and a Na containing target or one or more ZnNa binary alloy sputtering targets, in a preferably oxygen free environment, in an extra sputtering chamber added between chambers 22b and 22c in the apparatus shown in FIG. 3A. For the purposes of this disclosure, a zinc-based target means a target that comprises at least 30 weight percent zinc, such as 51-100 percent zinc. The composition of a ZnNa binary alloy sputtering target may comprise 0.01 to 4.0 weight percent sodium, more preferably 1.0 to 4.0 weight percent sodium and the balance being zinc and optionally less than 5 weight percent unavoidable impurities or intentionally added alloying elements. As in the embodiment illustrated in FIG. 1, the n-type semiconductor layer 302 may then be sputtered over layer 303 in chamber 22c. Layer 302 comprise any suitable n-type semiconductor material, such as (II,III)-VI semiconductor material comprises at least one of Zn and In, and at least one of S and Se, and optionally hydrogen and/or oxygen, including In-VI semiconductors, e.g. In₂Se₃, In₂S₃, In₂(Se₁₋ₓSₓ)₃, (In_{2±y}Zn_{1±y})Se₄, (In_{2±y}Zn_{1±y})S₄ or (In_{2±y}Zn_{1±y})(Se₁₋ₓSₓ)₄, where 0<x<1, 0≦y≦1 and (InₓZn₁₋ₓ)_{2+z} (Se_{y}S_{1-y})_{3+z}, where 0<x≦1, 0≦y≦1 and 0≦z≦1. In one aspect, layer 302 comprises a semiconductor material which contains both In and Zn. The second electrode 400 may then be deposited on the n-type semiconductor layer 302.

The solar cell is then annealed as shown in FIG. 4B before or after layer 302 deposition to cause the diffusion of Zn from the layer 303 into the p-type semiconductor absorber layer 301. The diffusing Zn reacts with Se in the p-type CIGS absorber layer 301 and forms an n-type semiconductor layer 305 (e.g., zinc doped CIGS) at the interface between the absorber layer 301 and the n-type semiconductor layer 302. The annealing may be carried out at temperatures ranging from 150 to 500° C. for 20 to 1000 seconds, preferably 200 to 400 seconds, by thermal, laser or flash lamp annealing. The annealing may be carried out in the Zn layer 303 sputtering chamber or in a separate chamber downstream from the Zn layer sputtering chamber. The boundary between the p-type absorber layer 301 and the n-type semiconductor layer 305 provides the pn junction for the solar cell. The deposited Zn layer 303 may be entirely or partially diffused into the CIGS layer 301 by annealing to form layer 305. For example, as shown in FIG. 4B, the entire sacrificial layer 303 is consumed.

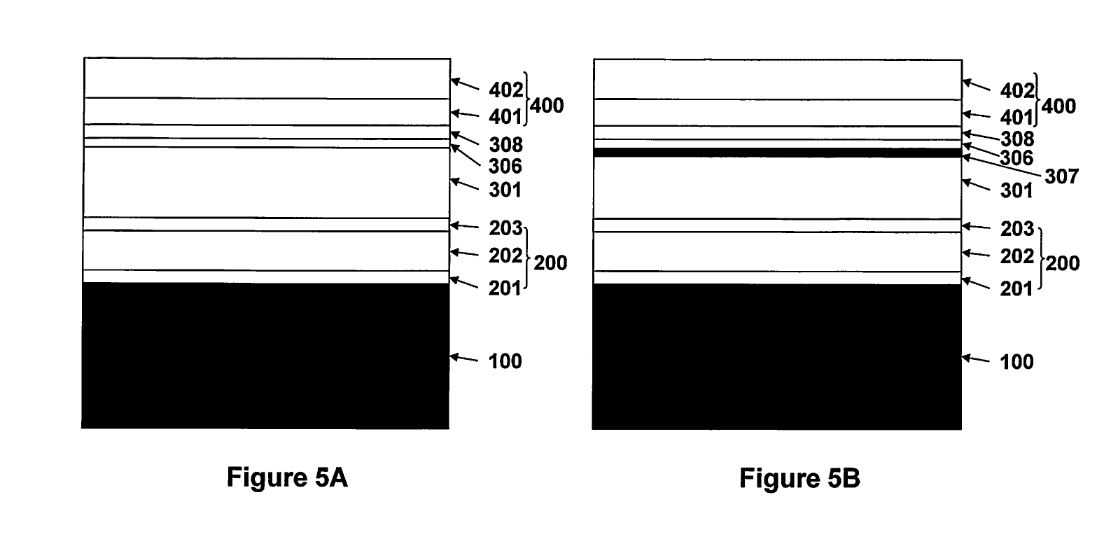

FIGS. 5A and 5B illustrate another embodiment of the invention. In this embodiment, as in the previous embodiments, a first electrode 200 is deposited on a substrate 100. The first electrode 200 may comprise an optional alkali diffusion barrier layer 201, a first transition metal layer 202 and a second transition metal layer 203. At least one p-type semiconductor absorber layer 301 is then deposited on the first electrode 200.

In this embodiment, rather than depositing a sacrificial metal layer 303 as shown in FIG. 4A, a Zn rich semiconductor buffer layer 306 is deposited on the absorber layer 301 instead, as shown in FIG. 5A. The first semiconductor buffer layer 306 is a Group VI deficient (II,III)-VI semiconductor layer deposited on the p-type semiconductor absorber layer 301. Then, a second (II,III)-VI semiconductor layer 308 is deposited on the first (II,III)-VI semiconductor layer 306. The two (II,III)-VI semiconductor layers 306, 308, have different compositions. The ratio of Group VI element to at least one of Group II or Group III elements (i.e., Group VI to metal atomic ratio) in the first (II,III)-VI semiconductor layer 306 is smaller than the ratio of the Group VI element to at least one of Group II or Group III elements in the second (II,III)-VI semiconductor layer 308. That is, the first (II,III)-VI semiconductor layer 306 has a lower concentration of Group VI element than the second (II,III)-VI semiconductor layer 308. The first (II,III)-VI semiconductor layer 306 is Group VI element poor (e.g., Zn rich) while the second (II,III)-VI semiconductor layer 308 is preferably stoichiometric. The first and second (II,III)-VI semiconductor layers 306, 308 may be deposited by any suitable method, such as by reactive sputtering described above. For example, the first (II,III)-VI semiconductor layer 306 is deposited by reactive sputtering in a sputtering atmosphere having a deficiency of Group VI element (e.g., sulfur) to form the Group VI element poor layer, while the second (II,III)-VI semiconductor layer 308 is deposited by reactive sputtering in a sputtering atmosphere having a stoichiometric ratio or excess of Group VI element. In an embodiment, the first (II,III)-VI semiconductor layer 306 comprises at least one of Zn and In and at least one of S and Se. The second (II,III)-VI semiconductor layer 308 may comprise, for example, at least one of Zn and In, and at least one of S and Se. For example, the p-type semiconductor absorber layer 301 may comprise CIGS:Na, the first (II,III)-VI semiconductor layer 306 may comprise a sulfur poor (i.e., Zn rich) ZnS layer having a composition Zn₁S₁₋ₓ, where 0<x<0.3, and the second (II,III)-VI semiconductor layer 308 comprise a stoichiometric ZnS layer (e.g., Zn₁S₁).

The solar cell is then annealed as shown in FIG. 5B before or after the second electrode 400 has been deposited on the second (II,III)-VI semiconductor layer 308. Annealing the solar cell causes diffusion of the excess Group II element, such as Zn, from the first (II,III)-VI semiconductor layer 306 into the p-type semiconductor absorber layer 301. The diffusing Group II element reacts with the p-type semiconductor absorber layer 301. This reaction results in the formation of an n-type II-VI semiconductor layer 307, such as a n-type ZnSe layer 307 in the top portion of the p-type CIGS absorber layer 301, at an interface between a resulting zinc sulfide layer and p-CIGS layer 301. As noted above, if the zinc diffusion from a zinc rich ZnS layer 306 into the CIGS layer 301 takes place at a relatively low temperature, such as less than about 200 C, then n-type zinc doped CIGS layer 307 forms at the interface of layers 301 and 306. In contrast, at higher temperatures, such as above 200 C, interdiffusion occurs between the adjacent layers 306 and 301 to form an n-type zinc selenide layer 307 between the CIGS 301 and ZnS 306 layers.

The step of annealing may further cause diffusion of Na from the p-CIGS:Na absorber layer 301 and/or from the semiconductor layer 306 if it contains sodium into the n-ZnSe layer 307 such that the n-ZnSe layer 307 comprises ZnSe:Na. If sodium is located interstitially rather than substitutionally on zinc sites in the lattice, then Na may act as an n-type rather than p-type dopant in ZnSe. As a result of the annealing, the first semiconductor layer 306 may be totally consumed (i.e., completely diffused into the CIGS layer 301 and/or combined with layer 308). Alternatively, a portion of the Group IV deficient first semiconductor layer 306 remains on top of the formed ZnSe layer 307 under the stoichiometric second (II,III) semiconductor layer 308. The resulting zinc sulfide layer 306 comprises either a stoichiometric ZnS layer if sufficient zinc diffused into layer 307 or layer 306 remains a sulfur poor zinc sulfide layer if the zinc to sulfur atomic ratio in layer 306 remains greater than 1 after formation of layer 307 by zinc diffusion from layer 306. After depositing the second (II,III)-VI semiconductor layer 308, the second electrode 400 may then deposited on the second (II,III)-VI semiconductor layer 308 before or after the annealing step.

Optionally, the reactive sputtering atmosphere may be monitored during deposition, such as with plasma emission spectroscopy, as described above. The reactive sputtering process may be controlled by providing at least one of S, Se, Zn, In, O₂ or H₂ into the reactive sputtering atmosphere based on the results of the monitoring during the deposition of the first and/or the second (II,III)-VI semiconductor layers 306, 308. Thus, the semiconductor layers 306 and/or 308 may optionally contain hydrogen and/or oxygen.

It is to be understood that the present invention is not limited to the embodiment(s) and the example(s) described above and illustrated herein, but encompasses any and all variations falling within the scope of the appended claims. For example, as is apparent from the claims and specification, not all method steps need be performed in the exact order illustrated or claimed, but rather in any order that allows the proper formation of the solar cells of the present invention.

What is claimed is:

1. A method of manufacturing a solar cell, comprising:
providing a substrate;
depositing a first electrode over the substrate;
depositing at least one p-type semiconductor absorber layer over the first electrode, wherein the p-type semiconductor absorber layer comprises a copper indium selenide (CIS) based alloy material;
depositing by reactive sputtering an n-type In-VI semiconductor layer over the at least one p-type semiconductor absorber layer; and
depositing a second electrode over the n-type In-VI semiconductor layer.

2. The method of claim 1, wherein the n-type In-VI semiconductor layer comprises In₂Se₃, In₂S₃, In₂(Se₁₋ₓSₓ)₃, (In_{2±y}Zn_{1±y})Se₄, (In_{2±y}Zn_{1±y})S₄ or (In_{2±y}Zn_{1±y})(Se₁₋ₓSₓ)₄, where 0<x<1, 0≦y≦1.

3. The method of claim 1, wherein the n-type In-VI semiconductor layer comprises (InₓZn₁₋ₓ)_{2+z}(Se_{y}S_{1-y})_{3+z}, wherein 0≦x≦1, 0≦y≦1, and 0≦z≦1.

4. The method of claim 1, further comprising:
forming buffer layer comprising a Zn metal layer or a Zn metal rich-Group VI element semiconductor layer between the absorber layer and the In-VI semiconductor layer; and
annealing the solar cell to cause diffusion of Zn from the buffer layer into the at least one p-type semiconductor absorber layer to form a n-ZnSe semiconductor layer at an interface between the absorber layer and the In-VI semiconductor layer.

5. The method of claim 1, wherein the first electrode comprises a first transition metal layer and an alkali element.

6. The method of claim 5, wherein the alkali element is selected from the group consisting of Li, Na, and K and the transition metal of the transition metal layer is selected from the group consisting of Mo, W, Ta, V, Ti, Nb, and Zr.

7. The method of claim 6, wherein:
the transition metal comprises Mo;
the alkali metal comprises Na; and
the copper indium selenide (CIS) based alloy material comprises p-CIGS:Na.

8. The method of claim 2, wherein the S in the n-type In-VI layer is provided in a hydrogen containing gas.

9. The method of claim 1, further comprising controlling a composition of the n-type In-VI semiconductor layer by providing at least one of O₂ or H₂ into a reactive sputtering atmosphere to form a (InₓZn₁₋ₓ)_{2+z} (Se_{y}S_{1-y})_{3+z} (O,H) layer, wherein 0≦x≦1 and 0≦y≦1.

10. The method of claim 1, further comprising monitoring a reactive sputtering atmosphere using plasma emission spectroscopy and controlling a composition of the reactive sputtering atmosphere based on the step of monitoring.

11. A method of manufacturing a solar cell, comprising:
providing a substrate;
depositing a first electrode over the substrate;
depositing at least one p-type semiconductor absorber layer over the first electrode, wherein the p-type semiconductor absorber layer comprises a copper indium selenide (CIS) based alloy material;
depositing by reactive sputtering a first (II,III)-VI semiconductor layer over the at least one p-type semiconductor absorber layer;
depositing by reactive sputtering a second (II,III)-VI semiconductor layer over the first (II,III)-VI semiconductor layer, wherein a ratio of Group VI element to at least one of Group II or Group III elements in the first (II,III)-VI semiconductor layer is smaller than the ratio of Group VI element to at least one of Group II or Group III elements in the second (II,III)-VI semiconductor layer; and
annealing the solar cell.

12. The method of claim 11, wherein the first (II,III)-VI semiconductor layer is a Group VI element poor and the second (II,III)-VI semiconductor layer is stoichiometric.

13. The method of claim 12, wherein the step of reactive sputtering the first (II,III)-VI semiconductor layer comprises sputtering in an sputtering atmosphere comprising a deficiency of Group VI element to form the Group VI element poor layer.

14. The method of claim 11, wherein the first (II,III)-VI semiconductor layer comprises at least one of Zn and In, and at least one of S and Se.

15. The method of claim 14, wherein the second (II,III)-VI semiconductor layer comprises at least one of Zn and In, and at least one of S and Se.

16. The method of claim 11, further comprising:
monitoring a reactive sputtering atmosphere using plasma emission spectroscopy; and
controlling the reactive sputtering atmosphere by providing at least one of S, Se, Zn, In, O₂ or H₂ into the reactive sputtering atmosphere based on the step of monitoring during reactive sputtering of at least one of the first or the second (II,III)-VI semiconductor layer.

17. The method of claim 11, wherein:
the step of depositing by reactive sputtering the first (II,III)-VI semiconductor layer over the at least one p-type semiconductor absorber layer comprises depositing a sulfur poor ZnS layer on a p-CIGS:Na layer;
the step of depositing by reactive sputtering the second (II,III)-VI semiconductor layer over the first (II,III)-VI semiconductor layer comprises depositing a stoichiometric ZnS layer; and
the step of annealing the solar cell causes diffusion of Zn from the first (II,III)-VI semiconductor layer into the at least one p-type semiconductor absorber layer and formation of a n-ZnSe semiconductor layer at an interface between a resulting zinc sulfide layer and p-CIGS:Na layer.

18. The method of claim 17, wherein:
the step annealing further causes diffusion of Na from the p-CIGS:Na layer into the n-ZnSe layer such that the n-ZnSe layer comprises a ZnSe:Na layer; and
the resulting zinc sulfide layer comprises a stoichiometric ZnS layer or a sulfur poor zinc sulfide sublayer located below a stoichiometric ZnS sublayer.

19. The method of claim 11, wherein the step of annealing the solar cell forms an n-type (II,III)-VI semiconductor layer on the at least one p-type semiconductor absorber layer.

20. A method of manufacturing a solar cell, comprising:
providing a substrate;
depositing a first electrode over the substrate;
depositing at least one p-type semiconductor absorber layer over the first electrode, wherein the p-type semiconductor absorber layer comprises a copper indium selenide (CIS) based alloy material;
depositing by reactive sputtering an n-type semiconductor layer over the at least one p-type semiconductor absorber layer; and
depositing a second electrode over the n-type semiconductor layer.

21. A solar cell comprising:
a substrate;
a first electrode over the substrate;
at least one p-type semiconductor absorber layer over the first electrode, wherein the p-type semiconductor absorber layer comprises a copper indium selenide (CIS) based alloy material;
a first sodium doped n-type (II,III)-VI semiconductor layer on the at least one p-type semiconductor absorber layer;
a second n-type (II,III)-VI semiconductor layer over the first n-type (II,III)-VI semiconductor layer; and
a second electrode over the a second n-type (II,III)-VI semiconductor layer.

22. The solar cell of claim 21, wherein:
the at least one p-type semiconductor absorber layer comprises p-CIGS:Na;
the first n-type (II,III)-VI semiconductor layer comprises n-ZnSe:Na; and
the second n-type (II,III)-VI semiconductor layer comprises n- Zn(S,Se).

23. The solar cell of claim 22, wherein the second n-type (II,III)-VI semiconductor layer comprises n-ZnS.

24. The solar cell of claim 23, further comprising a n-Zn₁S₁₋ₓ semiconductor layer between the n-ZnSe:Na and n-ZnS layers, wherein 0<x<0.3.

25. The solar cell of claim 21, wherein the first electrode comprises molybdenum containing sodium and the second electrode comprises a transparent conductive oxide selected from ZnO, ITO, AZO or a combination thereof.
